(19) United States
(12) Patent Application Publication
(10) Pub. No.: US 2008/0099913 A1
(43) Pub. Date: May 1, 2008

(54) METALLIZATION LAYER STACK WITHOUT A TERMINAL ALUMINUM METAL LAYER

(76) Inventors: Matthias Lehr, Dresden (DE); Frank Kuechenmeister, Dresden (DE); Lothar Lehmann, Radebeul (DE); Marcel Wieland, Radebeul (DE); Alexander Platz, Moritzburg (DE); Axel Walter, Radebeul (DE); Gotthard Jungnickel, Radebeul (DE)

Correspondence Address: WILLIAMS, MORGAN & AMERSON, 10333 RICHMOND, SUITE 1100, HOUSTON, TX, 77042, US

(21) Appl. No.: 11/752,519

(22) Filed: May 23, 2007

(30) Foreign Application Priority Data
Oct. 31, 2006 (DE) 10 2006 051 491.2

(51) Int. Cl. H01L 23/48; H01L 21/44

(52) U.S. Cl. 257/737; 438/614; 257/E23.167; 257/E21.476

(57) ABSTRACT

By directly forming an underbump metallization layer on a contact region of the last metallization layer, the formation of any other terminal metals, such as aluminum and corresponding adhesion/barrier layers, may be avoided. Consequently, the thermal and electrical behavior of the resulting bump structure may be improved, while process complexity may be significantly reduced.

### BACKGROUND OF THE INVENTION

1. Field of the Invention

The present disclosure generally relates to the formation of integrated circuits, and, more particularly, to a process flow for forming a metallization stack including a bump structure for connecting to an appropriately formed package or carrier substrate.

2. Description of the Related Art

In manufacturing integrated circuits, it is usually necessary to package a chip and provide leads and terminals for connecting the chip circuitry with the periphery. In some packaging techniques, chips, chip packages or other appropriate units may be connected by means of solder balls, formed from so-called solder bumps, that are formed on a corresponding layer, which will be referred to herein as a final contact layer, of at least one of the units, for instance on a dielectric passivation layer of the microelectronic chip. In order to connect the microelectronic chip with the corresponding carrier, the surfaces of two respective units to be connected, i.e., the microelectronic chip comprising, for instance, a plurality of integrated circuits and a corresponding package, have formed thereon adequate pad arrangements to electrically connect the two units after reflowing the solder bumps provided at least on one of the units, for instance on the microelectronic chip. In other techniques, solder bumps may have to be formed that are to be connected to corresponding wires or the solder bumps may be brought into contact with corresponding pad areas of another substrate acting as a heat sink. Consequently, it may be necessary to form a large number of bumps that may be distributed over the entire chip area, thereby providing, for example, the I/O capability as well as the desired low-capacitance arrangement required for high frequency applications of modern microelectronic chips that usually include complex circuitry, such as microprocessors, storage circuits and the like and/or include a plurality of integrated circuits forming a complete complex circuit system.

In modern integrated circuits, highly conductive metals, such as copper and alloys thereof, are increasingly used to accommodate the high current densities encountered during the operation of the devices. Consequently, the metallization layers may comprise metal lines and vias formed from copper or copper alloys, wherein the last metallization layer may provide contact areas for finally connecting to the solder bumps to be formed above the copper-based contact areas. The processing of copper in the subsequent process flow for forming the solder bumps, which is itself a highly complex manufacturing phase, may be performed on the basis of the well-established metal aluminum that has been effectively used for forming solder bump structures in complex aluminum-based microprocessors. Therefore, well-established processes and materials are available for processing aluminum, which may represent a well-approved interface between advance metallization schemes used in the lower laying metallization layers and the process flow for forming the bump structure. For processing the aluminum-based materials, an appropriate barrier and adhesion layer is formed on the copper-based contact area, followed by an aluminum layer. Subsequently, the contact layer including the solder bumps is formed on the basis of the aluminum-covered contact area.

In order to provide hundreds or thousands of mechanically well-fastened solder bumps on corresponding pads, the attachment procedure of the solder bumps requires a careful design since the entire device may be rendered useless upon failure of only one of the solder bumps. For this reason, one or more carefully chosen layers are generally placed between the solder bumps and the underlying substrate or wafer including the aluminum-covered contact areas. In addition to the important role these interfacial layers, herein also referred to as underbump metallization layers, may play in imparting a sufficient mechanical adhesion of the solder bump to the underlying contact area and the surrounding passivation material, the underbump metallization has to meet further requirements with respect to diffusion characteristics and current conductivity. Regarding the former issue, the underbump metallization layer has to provide an adequate diffusion barrier to prevent the solder material, frequently a mixture of lead (Pb) and tin (Sn), from attacking the chip's underlying metallization layers and thereby destroying or negatively affecting their functionality. Moreover, migration of solder material, such as lead, to other sensitive device areas, for instance into the dielectric, where a radioactive decay in lead may also significantly affect the device performance, has to be effectively suppressed by the underbump metallization. Regarding current conductivity, the underbump metallization, which serves as an interconnect between the solder bump and the underlying metallization layer of the chip, has to exhibit a thickness and a specific resistance that does not inappropriately increase the overall resistance of the metallization pad/solder bump system. In addition, the underbump metallization will serve as a current distribution layer during electroplating of the solder bump material. Electroplating is presently the preferred deposition technique, since physical vapor deposition of solder bump material, which is also used in the art, requires a complex mask technology in order to avoid any misalignments due to thermal expansion of the mask while it is contacted by the hot metal vapors. Moreover, it is extremely difficult to remove the metal mask after completion of the deposition process without damaging the solder pads, particularly when large wafers are processed or the pitch between adjacent solder pads is reduced.

Although a mask is also used in the electroplating deposition method, this technique differs from the evaporation method in that the mask is created using photolithography to thereby avoid the above-identified problems caused by physical vapor deposition techniques. After the formation of the solder bumps, the underbump metallization has to be patterned to electrically insulate the individual solder bumps from each other.

With reference to FIGS. 1a-1c, a typical conventional process flow will now be described to explain the methodology involved in forming solder bumps of copper-based semiconductor devices in more detail.

FIG. 1a schematically shows a cross-sectional view of a conventional semiconductor device 100 in an advanced manufacturing stage. The semiconductor device 100 comprises a substrate 101, which may have formed therein circuit elements and other microstructural features that are, for convenience, not shown in FIG. 1a. Moreover, the device 100 comprises one or more metallization layers including copper-based metal lines and vias, wherein, for convenience, the last metallization layer 107 is shown, which may comprise a dielectric material and formed therein a metal region 102 that is substantially comprised of copper or a copper alloy. The metallization layer 107 is covered by a corresponding passivation layer 103, except for at least a certain portion of the metal region 102. The passivation layer 103 may be comprised of any suitable dielectric material, such as silicon dioxide, silicon nitride, silicon oxynitride and the like. Formed above the copper-based metal region 102 is a barrier/adhesion layer 104, which may be comprised of tantalum, tantalum nitride, titanium, titanium nitride, tantalum nitride or compositions thereof and the like, wherein the barrier/adhesion layer 104 provides the required diffusion blocking characteristics as well as the corresponding adhesion between an overlying aluminum layer 105 and the copper-based metal region 102. The aluminum layer 105 in combination with the adhesion/barrier layer 104 may be referred to as a terminal metal. The aluminum layer 105 thus defines, in combination with the patterned passivation layer 103, the barrier/adhesion layer 104 and the underlying copper-based metal region 102, a contact region 105A, above which a solder bump is to be formed. Moreover, a corresponding resist mask 106 is formed on the device 100 to protect the contact region 105A while exposing the residue of the layer 105 to an etch ambient 108 that typically includes chlorine-based chemicals for efficiently removing aluminum.

The semiconductor device 100 as shown in FIG. 1a may be formed by the following processes. First, the substrate 101 and any circuit elements contained therein may be manufactured on the basis of well-established process techniques, wherein, in sophisticated applications, circuit elements having critical dimensions as small as approximately 50 nm and even less may be formed, followed by the formation of the one or more metallization layers 107 including copper-based metal lines and vias, wherein, typically, low-k dielectric materials are used for embedding at least the metal lines. Next, the passivation layer 103 may be formed on the last metallization layer 107 by any appropriate deposition technique, such as plasma enhanced chemical vapor deposition (PECVD) and the like. Thereafter, a standard photolithography process is performed to form a photoresist mask (not shown) having a shape and dimension that substantially determines the shape and dimension of the contact region 105A and thus substantially determines, in combination with the material characteristics of the layers 105 and 104, the contact resistance of the finally obtained electrical connection between the metallization layer 107, i.e., the copper-based metal region 102, and a solder bump to be formed above the contact region 105A. Subsequently, the passivation layer 103 may be opened on the basis of the resist mask, which may then be removed by well-established resist removal processes that may include appropriate cleaning steps, as required.

Thereafter, the barrier/adhesion layer 104 may be deposited, for instance by sputter deposition, using well-established process recipes for tantalum, tantalum nitride, titanium, titanium nitride or other similar metals and compounds thereof as are typically used in combination with copper metallizations to effectively reduce copper diffusion and enhance adhesion of the overlying aluminum layer 105. Next, the aluminum layer 105 may be deposited, for instance by sputter deposition, chemical vapor deposition and the like, followed by a standard photolithography process for forming the resist mask 106. Next, the reactive etch ambient 108 is established, which may require a complex chlorine-based etch chemistry, wherein the process parameters may require an accurate process control to substantially prevent undue yield loss. The etch process 108 may also comprise a separate etch step for etching through the barrier/adhesion layer 104 and may also include a wet strip process for removing any corrosive etch residues generated during the complex aluminum etch step.

FIG. 1b schematically shows the semiconductor device 100 in a further advanced manufacturing stage, in which a further passivation layer 109, which may also referred to as a final passivation material or layer, is formed above the contact region 105A and the passivation layer 103, followed by a resist mask 110, which is configured to act as an etch mask in a subsequent etch process for opening the final passivation layer 109. The layer 109 may be formed on the basis of well-established spin-on techniques or other deposition methods, while the resist mask 110 may be formed on the basis of established photolithography techniques. Based on the resist mask 110, the final passivation layer 109, typically comprised of polyimide, may be etched to expose at least a portion of the contact region 105A.

According to alternative approaches, the aluminum layer 105 and the barrier/adhesion layer 104 may be deposited on the metallization layer 107 prior to the formation of the passivation layer 103. Thereafter, the passivation layer 103 may be patterned, followed by the highly complex aluminum etch process 108, including any etch and cleaning processes for also patterning the barrier/adhesion layer 104. Thereafter, the final passivation layer 109 may be deposited and the further processing may be continued, as is also described above with reference to FIG. 1b.

FIG. 1c schematically shows the semiconductor device 100 in a further advanced manufacturing stage. Here, the device 100 comprises an underbump metallization layer 111, which is shown in this example as comprising at least a first underbump metallization layer 111A and a second layer 111B, which are formed on the patterned final passivation layer 109 and on the contact region 105A. The underbump metallization layer 111 may be comprised of an appropriate layer combination to provide the required electrical, thermal and mechanical characteristics, as well as for reducing or avoiding a diffusion of material of an overlying solder bump 112 into lower lying device regions. Moreover, a resist mask 113 is formed which comprises an opening that substantially defines the shape and lateral dimensions of the solder bump 112.

Typically, the device 100 as shown in FIG. 1c may be formed by the following processes. First, the underbump metallization layer 111, for instance the layer 111B, may be formed by sputter deposition for forming a titanium tungsten layer (TiW), since this material composition is frequently used in view of its well-approved diffusion blocking and adhesion characteristics. Thereafter, further sub-layers of the underbump metallization layer 111 may be formed, such as the layer 111A, which may be provided in the form of a chromium/copper layer, which may be followed by a further substantially pure copper layer. The layer(s) 111A may be formed by sputter deposition in accordance with well-established recipes. Next, a further photolithography process is performed in order to form the resist mask 113, thereby providing a deposition mask for the subsequent electroplating process for the deposition of the solder bump 112. Thereafter, the resist mask 113 may be removed and the underbump metallization layer 111 may be patterned while using the solder bump 112 as an etch mask, thereby providing electrically insulated solder bumps 112. Depending on process requirements, the solder bumps 112 may be reflowed to create rounded solder balls (not shown) which may then be used for contacting an appropriate carrier substrate.

As is evident from the process flow described with reference to FIGS. 1a-1c, a highly complex process flow is required for providing the contact region 105A so as to enable the formation of the bump structure including the solder bump 112 and the underlying underbump metallization layer 111. Furthermore, even though the highly conductive copper is used for the metal region 102, the finally achieved contact resistance of the bump structure is significantly affected by the characteristics of the contact region 105A, i.e., by the aluminum layer 105 and the barrier/adhesion layer 104. Consequently, in the conventional procedure, a highly complex process flow, including the complex aluminum etch sequence, is involved while only resulting in a moderate electrical performance of the resulting bump structure. In addition, aluminum pitting and also delamination of the final passivation layer 109, typically comprised of polyimide, may occur, which may especially be caused by open copper areas, i.e., by areas similar to the region 102, that are referred to as open areas, typically provided at the die edge region so as to act as a die border, or in scribe lanes of the wafer when these scribe lanes are provided on the front side. In these open areas, the final passivation layer 109 may not be provided, thereby promoting delamination of the polyimide layer 109 at any interfaces between open areas and regular die regions. Thus, aluminum pitting and/or polyimide delamination may significantly contribute to yield loss in the above-described manufacturing sequence.

The present disclosure is directed to various devices and methods that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein is directed to a technique that enables the formation of a bump structure including an underbump metallization layer and a solder bump or any other adhesive material bumps directly on a contact area of the last metallization layer, such as a copper-based metal region, thereby avoiding highly complex barrier/adhesion and aluminum deposition and patterning processes. Thus, compared to conventional process strategies, the manufacturing sequence may be designed more efficiently, thereby reducing manufacturing costs, while at the same time providing enhanced performance with respect to the electrical, mechanical and thermal characteristics of the resulting bump structure.

According to one illustrative embodiment disclosed herein, a semiconductor device comprises a metallization layer comprising a contact region laterally bordered by a passivation layer and having a contact surface. The device further comprises a final passivation layer formed above the passivation layer and exposing at least a portion of the contact region. An underbump metallization layer is formed on the contact surface and a portion of the final passivation layer and a nickel-containing intermediate layer is formed on the underbump metallization layer. Finally, a bump is formed on the nickel-containing intermediate layer.

In accordance with another illustrative embodiment disclosed herein, a method comprises forming an underbump metallization layer on an exposed contact surface of a contact region of a last metallization layer of a semiconductor device. The method further comprises forming a nickel-containing intermediate layer on the underbump metallization layer and forming a bump on the intermediate nickel-containing layer above the contact surface. Additionally, the underbump metallization layer is patterned in the presence of the bump.

According to yet another illustrative embodiment disclosed herein, a method comprises forming a nickel-containing layer above a last metallization layer of a semiconductor device, wherein the nickel-containing layer is formed by a wet chemical process. Moreover, a bump structure is formed above the nickel-containing layer.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1c schematically show cross-sectional views of a conventional semiconductor device during the formation of a bump structure above a copper-based metal region of a last metallization layer; and

FIGS. 2a-2d schematically show cross-sectional views of a semiconductor device during the formation of a bump structure directly on a copper-containing surface in accordance with illustrative embodiments disclosed herein.

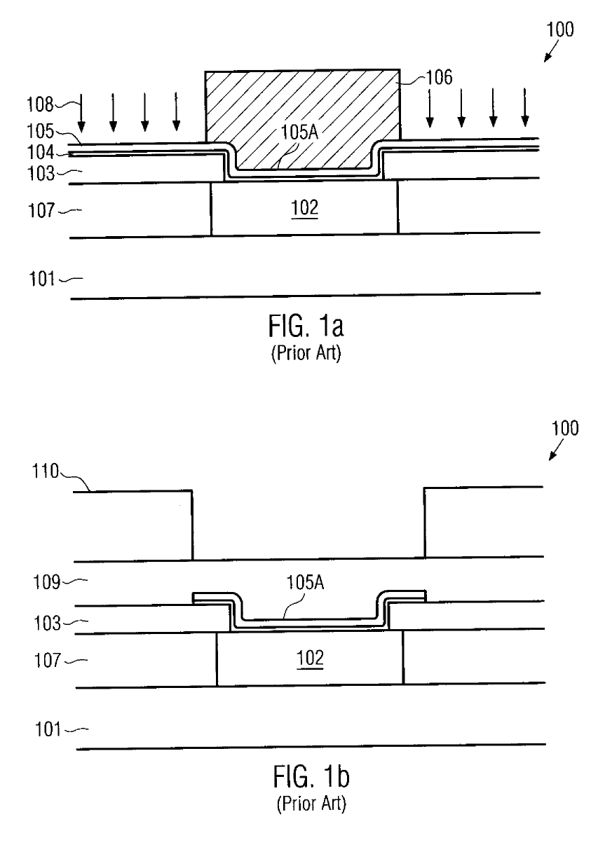

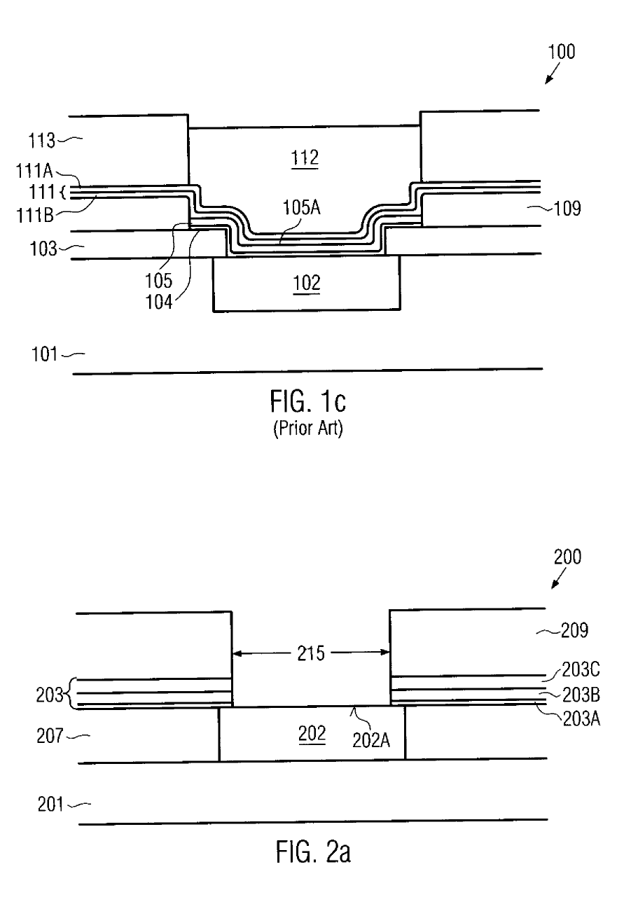

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter disclosed herein contemplates an improved technique for forming a bump structure, in which the performance of an advanced metallization, such as copper-based metallization, and the corresponding manufacturing sequence for forming the bump structure may be enhanced by omitting the formation of a terminal metal layer, such as an aluminum layer, on top of a metal region, such as copper-containing region, of the last metallization layer by appropriately adapting the process flow for forming the final metallization layer and the process flow and the materials for forming a bump structure including a final passivation layer. By avoiding the deposition of, for instance, a terminal aluminum layer, generally the complexity of the overall process flow may be significantly reduced, thereby saving on production costs, while at the same time the electrical and/or mechanical and/or thermal characteristics of the resulting bump structure may be improved, or, for a given performance of the bump structure, the dimensions of the bump structure may be correspondingly reduced compared to a conventional semiconductor device. For example, a semiconductor device having a bump structure of the same dimensions as a conventional device may have a significantly improved current drive capability and may also provide enhanced heat dissipation due to the enhanced thermal and electrical conductivity of the resulting bump structure achieved by the omission of the additional and less conductive terminal metal layer.

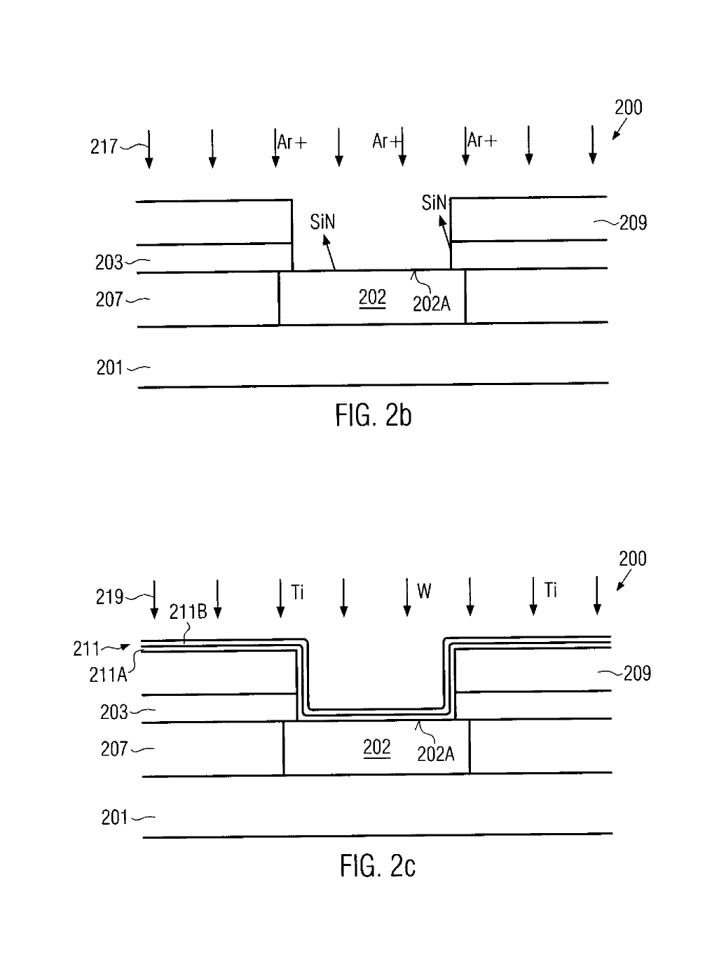

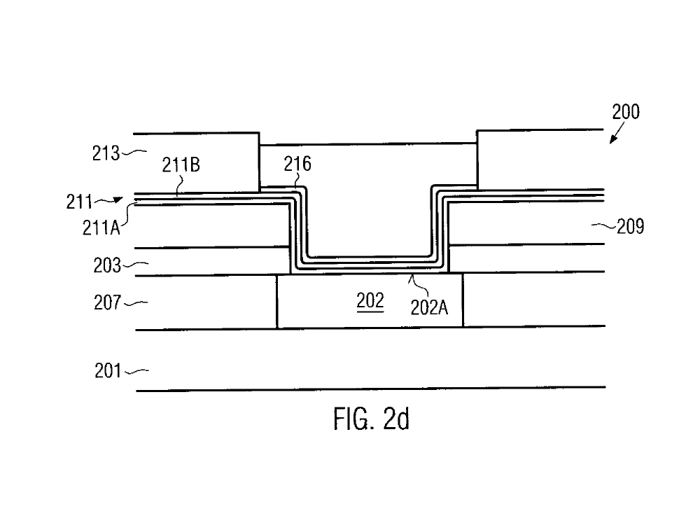

FIG. 2a schematically shows a cross-sectional view of a semiconductor device 200 in an advanced manufacturing stage. The device 200 comprises a substrate 201, which may represent any appropriate substrate for the formation of integrated circuits, such as a bulk silicon substrate, a silicon-on-insulator (SOI) substrate, a glass substrate having formed thereon any appropriate semiconductor layer for forming circuit elements, or any other compound semiconductor material, such as II-VI and/or III-V semiconductors, and the like. Thus, a plurality of circuit elements (not shown), possibly in combination with other microstructural features, such as mechanical and optical elements and the like, may be formed in and on the substrate 201. Formed above the substrate 201 are one or more metallization layers 207, wherein, for convenience, the metallization layer 207 may represent the very last layer, comprising an appropriate dielectric material, such as silicon dioxide, silicon nitride, fluorine-doped silicon oxide, any low-k dielectric materials having a relative permittivity of 3.0 or less, or any combination thereof. Moreover, the metallization layer 207 may comprise a contact region 202, which, in advanced devices, may be a copper-based metal region, that is, a metal region that contains a significant portion of copper so as to provide superior thermal and electrical conductivity. It should be appreciated that the contact region 202 may include other metals or conductive materials, for instance any barrier/adhesion layers formed at an interface to the surrounding dielectric material of the metallization layer 207. The contact region 202 comprises a contact surface 202A on which a bump structure is to be directly formed so as to provide enhanced thermal and electrical conductivity between the bump structure still to be formed and the metallization layer 207.

The metallization layer 207 may be covered by a passivation layer 203, except for the copper-containing surface 202A, wherein the passivation layer 203 may be comprised of any appropriate dielectric material, such as silicon dioxide, silicon nitride, silicon carbide, nitrogen-enriched silicon carbide, a low-k dielectric material, or any appropriate combination of these materials. For example, the passivation layer 203 may be formed of two or more sub-layers 203A, 203B, 203C, wherein, for instance, the lowest sub-layer 203A may provide a diffusion blocking effect to substantially suppress any out-diffusion of copper into neighboring device regions. The layer 203A may further exhibit appropriate etch stop characteristics during the patterning of the layer 203. For instance, nitrogen-enriched silicon carbide may be used. In other cases, the layer 203A may be omitted and the further layers 203B and 203C may provide the desired overall characteristics. For example, silicon oxynitride in combination with silicon nitride may be used, while, in other embodiments, silicon dioxide and silicon nitride may be combined. However, in other cases, any other composition of the passivation layer 203 may be used, depending on the device requirements.

Moreover, in some illustrative embodiments, the surface 202A may be covered by a protection layer (not shown), which, in one illustrative embodiment, may represent a portion of the passivation layer 203, such as the layer 203A. In other illustrative embodiments, the protection layer may be formed as a separate layer on the passivation layer 203 and on the surface 202A. The respective protection layer may be comprised of any appropriate dielectric material, such as silicon nitride, silicon carbide, nitrogen-enriched silicon carbide and the like, and substantially protects the surface 202A during the further processing and handling of the semiconductor device 200.

Furthermore, in the embodiment shown, the device 200 comprises a final passivation material 209, which, in some illustrative embodiments, may be comprised of polyimide and the like. In other embodiments, the final passivation material 209 may be comprised of a photosensitive material, such as photosensitive polyimide. Moreover, an opening 215 may be defined in the layers 203, at least in an upper portion thereof, when the surface 202A may still be covered by a portion of the layer 203, and in the layer 209. The lateral size of the opening 215 may substantially define the size of the final contact area connecting to the last metallization layer 207 after exposing the surface 202A and forming a respective bump structure thereon.

A typical process flow for forming the semiconductor device 200 as shown in FIG. 2a may comprise the following processes. After the formation of any circuit elements and possibly of other microstructural features in and on the substrate 201 in accordance with predefined process recipes and design rules, the one or more metallization layers 207 may be formed on the basis of well-established damascene techniques for forming copper-based metal lines and vias. During the formation of the metallization layers 207, the contact region 202 having the surface 202A may also be formed. Thereafter, the passivation layer 203 may be formed by any appropriate deposition technique, such as PECVD, in order to reliably cover the metallization layer 207. As previously explained, the passivation layer 203 may comprise a material that substantially suppresses an out-diffusion of copper atoms into neighboring device regions. Then, in one illustrative embodiment, the final passivation layer may be deposited, for instance on the basis of spin-on techniques and the like. For example, the material 209 may be applied as a photosensitive material that may be patterned on the basis of a lithography process for selectively exposing the material 209. Next, the material 209 may be patterned on the basis of the latent image formed in the material 209 by the preceding exposure process. Thereafter, the patterned material 209 may be used as an etch mask for etching the passivation layer 203 on the basis of well-established etch techniques. As previously explained, in some embodiments, the patterning of the layer 203 may be stopped prior to completely exposing the surface 202A, if a protection layer may be desirable for the further handling of the substrate 201. For example, the layer 203A, which may act as an etch stop layer, may be opened immediately prior to a process for forming a further material on the surface 202A. However, other process flow regimes may be used for patterning the material 209 and the layer 203. For instance, a resist mask may be formed above the material 209, and the material 209 and the layer 203 may be patterned on the basis of the resist mask, which, in some embodiments, may be accomplished in a common etch process, while, in other cases, the resist mask may be removed after etching the material 209, which may then act as an etch mask for the layer 203. As previously discussed, due to the superior thermal and electrical conductivity of the bump structure still to be formed, the dimension of the opening 215 may be selected less than in conventional devices having a comparable thermal and electrical conductivity. Consequently, significant material savings may be achieved in subsequent processes for the formation of solder bumps and the like. On the other hand, for a predefined dimension of the opening 215, the finally achieved thermal and electrical conductivity may be significantly enhanced compared to a conventional device.

FIG. 2b schematically shows the semiconductor device 200 in a further advanced manufacturing stage, wherein the surface 202A may be reliably covered by a protection layer, such as the layer 203A, while, in other embodiments, the surface 202A may be exposed and may require a cleaning treatment prior to the subsequent deposition of an underbump metallization layer. Thus, the device 200 is shown to be subjected to an appropriately designed surface treatment process 217 so as to expose and/or clean the surface 202A. In one illustrative embodiment, the process 217 is designed as a pre-cleaning process as typically used prior to sputter depositing any appropriate metal onto an exposed copper surface. Thus, the process 217 may be designed as a pre-sputter process with appropriately selected parameters to provide a sufficient bombardment of an inert species, such as argon and the like, in order to remove unwanted material, which may, for instance, be comprised of silicon nitride, nitrogen-containing silicon carbide and the like. Consequently, during the process 217, the surface 202A may be increasingly exposed, while, at the same time, the ongoing ion bombardment substantially suppresses the formation of non-desired discolorations and oxidized portions on the surface 202A. In one embodiment, the process parameters, i.e., the supply of precursor materials, of the process 217 for removing the material from the surface 202A may be modified in situ so as to subsequently establish a sputter deposition atmosphere in order to form a conductive underbump metallization layer on exposed portions of the final passivation layer 209 and the exposed surface 202A. It should be appreciated that other patterning regimes may also be used, wherein the final passivation layer 209 may be patterned to have an opening of a different size compared to a respective opening formed in the passivation layer 203. In this case, two different patterning processes may be used, wherein the treatment 217 may act on the various exposed portions of the layers 209 and 203, while the subsequent deposition process may also form material on exposed horizontal portions of the layer 203.

FIG. 2c schematically shows the semiconductor device 200 during the formation of an underbump metallization layer 211, or at least a sub-layer 211B thereof, by means of a sputter deposition process 219. In illustrative embodiments, the sputter deposition process 219 may be designed to form any appropriate metal or metal compound, such as titanium tungsten, tantalum, titanium, titanium nitride, tantalum nitride, tungsten, tungsten silicide, titanium silicide, tantalum silicide, or nitrogen-enriched tungsten, tantalum and titanium silicides and the like. In these embodiments, the process 217 (FIG. 2b) may have been performed in situ as a pre-cleaning process, wherein, after the removal of unwanted material from the surface 202A, the ratio of argon ions and metal ions and other precursor materials, such as nitrogen and silicon, if required, may be changed in such a way that an efficient deposition of the layer 211B may be achieved. Consequently, the underbump metallization layer 211, i.e., the first sub-layer 211B thereof, is directly deposited on the exposed surface 202A without requiring the provision of any intermediate terminal metal as is used in the conventional technique. In one illustrative embodiment, the sub-layer 211B is provided in the form of a titanium layer, thereby providing desired adhesion and barrier properties. After the formation of the sub-layer 211B, one or more further sub-layers of any appropriate material composition may be deposited, for instance by sputter deposition, electrochemical deposition, chemical vapor deposition (CVD) and the like, so as to complete the underbump metallization layer 211 in accordance with device requirements. For example, in one embodiment, a copper-containing layer may be formed in order to act as a seed layer for a subsequent wet chemical deposition process for depositing a nickel-containing material. Thus, in some illustrative embodiments, the underbump metallization layer 211 may comprise the first sub-layer 211B comprising titanium and a second sub-layer 211A comprising copper and/or any other appropriate seed material for initializing a subsequent wet chemical deposition process. It should be appreciated, however, that any other layer sequence and material composition may be provided on the layer 211.

FIG. 2d schematically shows the device 200 in a further advanced manufacturing stage. A resist mask 213 is provided that defines the lateral dimensions of a bump 212 formed within an opening of the resist mask 213. Furthermore, an intermediate layer 216, which in some illustrative embodiments may be a nickel-containing layer, is formed between the underbump metallization layer 211 and the bump 212. In one embodiment, the intermediate layer 216 may be comprised of nickel, while in other embodiments a nickel compound may be used. In still other embodiments, a nickel- and copper-containing layer stack may be provided, thereby increasing the conductivity of the bump structure. The nickel material in the intermediate layer 216 may provide enhanced performance during the subsequent processes for forming the bump 212 and with respect to the operational behavior. In some illustrative embodiments, the intermediate layer 216 may also be formed below the resist mask 213, thereby even further enhancing the efficiency of the underbump metallization layer 211 during the subsequent wet chemical deposition process for forming the bump.

The bump 212 may be comprised of any appropriate material composition, such as lead and tin with a high lead content, or the material may represent an eutectic compound. In still other cases, substantially lead-free compounds, such as tin/silver mixtures and the like, may be used. In other embodiments, any appropriate material composition may be used according to device requirements. By providing the intermediate layer 216 within the opening 215, enhanced flexibility in wet chemically depositing a desired material composition may be achieved, since, for instance, nickel-containing materials may be efficiently deposited by electroplating or electroless plating, thereby providing a highly uniform and conductive “buffer” layer for the actual bump material. Furthermore, nickel may provide a high conductivity in combination with a high compatibility with a plurality of bump materials, such as lead-containing materials and lead-free materials.

The layer or layers 211 may be formed by any appropriate deposition technique, followed by well-established photolithography techniques for forming and patterning the resist mask 213. Thereafter, the intermediate layer 216 may be formed, in some embodiments, by an electroplating process and/or by an electroless plating process, wherein the underbump metallization layer 211, that is the layer 211A, may act as a seed layer or a catalyst material. Hence, a reliable and substantially uniform bottom layer for confining the bump material may be provided. In other embodiments, the intermediate layer 216 may be formed prior to forming the resist mask 213, when an enhanced current distribution effect of the underbump metallization layer 211 is desired.

Thereafter, the bump 212 may be formed by electroplating using the underbump metallization layer 211 as a current distribution layer, while the resist mask 213 defines the lateral dimensions of the bump 212. Thus, the device 200 comprises a bump structure including the bump 212 and the underbump metallization layer 211, which is directly formed on the contact region 202, i.e., on the surface 202A, with the intermediate layer 216 acting as a buffer between the bump 212 and the underbump metallization layer 211. Furthermore, due to avoiding the provision of the terminal layer, as previously explained, the thermal and electrical conductivity between the contact region 202 and the bump 212 may be significantly improved, while process time may also be reduced.

Thereafter, the further manufacturing process may be resumed by removing the resist mask 213, based on well-established resist removal techniques, and thereafter the underbump metallization layer 211 may be patterned in the presence of the bump 212 so as to form electrically insulated bumps 212. The patterning process for the underbump metallization layer 211 may include wet chemical and/or electrochemical and/or plasma-based etch techniques. Thereafter, in some embodiments, the bump 212 may be formed into a solder ball by appropriately reflowing the solder material. In other examples, the bumps 212 may be used for contacting an appropriate carrier substrate without a previous reflow process.

As a result, the subject matter disclosed herein provides an enhanced technique for forming a bump structure comprising a bump and an underbump metallization layer directly on a contact region, such as a copper-based contact region, so that the underbump metallization layer directly contacts the surface of the contact region, without providing additional buffer materials as an interface for aluminum-based process flows. In this respect, the term underbump metallization layer is to be understood as a layer that not only provides the required thermal, electrical and mechanical characteristics to obtain a good adhesion and performance of a bump formed above the copper-based contact region, but also serves in its entirety as a current distribution layer during the electrochemical formation of bumps, such as solder bumps. Consequently, since the bump structure provided by the subject matter disclosed herein lacks any terminal metal layers, such as an aluminum layer and a corresponding adhesion/barrier layer, current drive capability as well as the thermal conductivity may be significantly enhanced, thereby providing the possibility of further reducing the lateral dimensions of the bump structure and/or operating the device under sophisticated operating conditions, due to the enhanced heat dissipation and current drive capabilities. Moreover, disadvantageous effects, such as aluminum pitting and delamination of passivation layers, especially caused by open regions and wafer scribe lanes, may be significantly reduced due to the enhanced adhesion of the last passivation layer to the underlying metallization layer stack. Moreover, the overall process flow for forming a highly efficient bump structure is significantly reduced in terms of complexity and materials so that remarkable cost savings may be achieved. In addition, the possibility of generally reducing the size of solder bumps, the formation of which may, in sophisticated applications, require the provision of highly expensive radiation reduced lead, may also contribute to a significant reduction in production costs. In addition, the omission of complex aluminum deposition and patterning processes may result in reduced cycle time. The provision of an intermediate material, such as a nickel-containing layer, may provide increased flexibility of selecting appropriate underbump materials and bump materials, substantially without reducing the thermal and electrical performance of the bump structure. The intermediate layer may be efficiently formed on the basis of electrochemical deposition techniques, thereby providing high process compatibility with the subsequent deposition regime.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor device, comprising:
a metallization layer comprising a contact region laterally bordered by a first passivation layer and having a contact surface;
a final passivation layer formed above said first passivation layer and exposing at least a portion of said contact region;
an underbump metallization layer formed on said contact surface and a portion of said final passivation layer;
a nickel-containing intermediate layer formed on said underbump metallization layer; and
a bump formed on said nickel-containing intermediate layer.

2. The semiconductor device of claim 1, wherein said underbump metallization layer is substantially free of aluminum.

3. The semiconductor device of claim 2, wherein said underbump metallization layer is formed on a portion of said first passivation layer and a portion of said final passivation layer.

4. The semiconductor device of claim 1, wherein said contact surface is a copper-containing surface.

5. The semiconductor device of claim 1, wherein said nickel-containing intermediate layer comprises a nickel compound.

6. The semiconductor device of claim 1, wherein said nickel-containing intermediate layer comprises a stack of at least one nickel layer and at least one copper-containing layer.

7. The semiconductor device of claim 1, wherein said underbump metallization layer comprises a first layer comprising titanium and a second layer comprising copper, said first layer being formed on said contact surface.

8. A method, comprising:
forming an underbump metallization layer on an exposed contact surface of a contact region of a last metallization layer of a semiconductor device;
forming a nickel-containing intermediate layer on said underbump metallization layer;
forming a bump on said intermediate nickel-containing layer above said contact surface; and
patterning said underbump metallization layer in the presence of said bump.

9. The method of claim 8, further comprising forming a first passivation layer above said contact surface and a dielectric material enclosing said contact region, forming a final passivation material on said first passivation layer and patterning said final passivation material and said first passivation layer to expose a portion of said contact surface.

10. The method of claim 9, wherein patterning said final passivation material and said first passivation layer comprises patterning said final passivation layer, and patterning said first passivation layer using said patterned final passivation layer as an etch mask.

11. The method of claim 9, wherein forming said first passivation layer comprises depositing at least two different material layers.

12. The method of claim 8, wherein forming said nickel-containing intermediate layer comprises depositing a nickel-containing material by a wet chemical deposition process.

13. The method of claim 8, wherein forming said bump comprises forming a deposition mask on said underbump metallization layer and forming said nickel-containing intermediate layer and said bump on the basis of said deposition mask.

14. The method of claim 8, wherein forming said bump comprises forming said nickel-containing intermediate layer on said underbump metallization layer and forming said bump on the basis of a deposition mask.

15. The method of claim 8, further comprising exposing said contact surface and forming said underbump metallization layer in a common process sequence.

16. A method, comprising:
forming a nickel-containing layer above a last metallization layer of a semiconductor device, said nickel-containing layer being formed by a wet chemical process; and
forming a bump structure above said nickel-containing layer.

17. The method of claim 16, further comprising forming an underbump metallization layer on an exposed contact area of said last metallization layer prior to forming said nickel-containing layer.

18. The method of claim 16, further comprising depositing a first passivation layer and a final passivation layer above said last metallization layer prior to exposing said contact area.

19. The method of claim 18, wherein patterning said first passivation layer comprises providing said final passivation layer is a photosensitive material, patterning said final passivation layer and using said patterned final passivation layer as an etch mask for patterning said first passivation layer.

20. The method of claim 17, wherein forming said underbump metallization layer comprises forming an adhesion/barrier layer on said exposed contact area and forming a seed layer on said adhesion/barrier layer.
